(19) United States
(12) Patent Application Publication
(10) Pub. No.: US 2021/0408469 A1
(43) Pub. Date: Dec. 30, 2021

(54) OLED DISPLAY PANEL AND MANUFACTURING METHOD THEREOF

(71) Applicant: Wuhan China Star Optoelectronics Semiconductor Display Technology Co., Ltd., Wuhan, Hubei (CN)

(72) Inventor: Jian YE, Hubei (CN)

(21) Appl. No.: 16/764,207

(22) PCT Filed: Mar. 19, 2020
(86) PCT No.: PCT/CN2020/080186

§ 371 Date: May 14, 2020

(30) Foreign Application Priority Data
Feb. 12, 2020 (CN) 202010094201.8

(51) Int. Cl. H01L 51/52; H01L 51/56

(52) U.S. Cl. CPC H01L 51/5253; H01L 51/56; H01L 51/525

(57) ABSTRACT

The present invention provides an OLED display panel. The OLED display panel includes a substrate including a display region, and a first region and a second region disposed around the display region in order; a light-emitting function layer disposed on the display region; a retaining wall disposed on the first region; and a thin film packing layer disposed on the light emitting functional layer and extending to the retaining wall through the second region. Wherein, the thin film packing layer includes a first inorganic layer, an organic layer, and a second inorganic layer arranged in a stack, and a notch is provided on the first inorganic layer disposed in the second region.

### FIELD OF INVENTION

The present invention relates to the field of display technologies, and in particular, to an OLED display panel and a manufacturing method thereof.

### BACKGROUND OF INVENTION

Organic light emitting diodes (OLEDs) have advantages of light weight, wide viewing angles, fast response times, low temperature resistance, and high luminous efficiency, so they are regarded as next-generation new display technologies. In order to achieve packaging of OLED devices, thin film packaging has gradually become a mainstream packaging technology.

In thin-film packaging structures, an inorganic/organic/inorganic overlapping film layer structure is often used as a water-blocking and oxygen-blocking layer to prevent an intrusion of external water vapor and oxygen. However, due to fluidity of organic layer material, when an organic layer is formed by an inkjet printing method, the organic layer material easily diffuses and overflows, resulting in poor packaging effect.

### TECHNICAL PROBLEM

The present invention provides an OLED display panel and a manufacturing method thereof. By defining a notch on a first inorganic layer in a second region around a periphery of a display region, the notch can accommodate flowable organic materials, so that inkjet printed organic materials have a greatly reduced flow velocity at the periphery of the display region, which can effectively prevent the organic materials from diffusing and overflowing, thereby improving packaging effect of a thin film packaging layer.

### TECHNICAL SOLUTION

An embodiment of the present invention provides an OLED display panel and a manufacturing method thereof, so as to solve a technical problem that an organic layer material in a thin film packaging structure easily diffuses and overflows and reduces the packaging effect.

The present invention provides an OLED display panel comprising:

a substrate comprising a display region, a first region disposed around the display region, and a second region disposed between the display region and the first region, wherein the second region is disposed around the display region;

a light-emitting function layer disposed on the display region;

a retaining wall disposed on the first region; and

a thin film packing layer disposed on the light emitting functional layer and extending to the retaining wall through the second region;

wherein the thin film packing layer comprises a first inorganic layer, an organic layer, and a second inorganic layer disposed in a stack, and a notch is defined in the first inorganic layer disposed in the second region.

In the OLED display panel provided in the present invention, the first inorganic layer is provided with one notch, and the notch is disposed along a direction surrounding the display region.

In the OLED display panel provided in the present invention, the first inorganic layer is provided with multiple notches, and the notches are disposed at intervals along a direction surrounding the display region.

In the OLED display panel provided in the present invention, each of a plurality of first spacers is between adjacent notches, and a sum of lengths of the plurality of notches is greater or less than a sum of lengths of the plurality of first spacers.

In the OLED display panel provided in the present invention, the display region comprises a first diagonal corner portion and a second diagonal corner portion disposed opposite to each other, and a third diagonal corner portion and a fourth diagonal corner portion disposed opposite to each other; and

the first diagonal corner portion, the second diagonal corner portion, the third diagonal corner portion, and the fourth diagonal corner portion are correspondingly provided with the notches.

In the OLED display panel provided in the present invention, the display region further comprises a first end portion, a second end portion, a third end portion, and a fourth end portion, the first end portion is disposed between the first diagonal corner portion and the fourth diagonal corner portion, the second end portion is disposed between the first diagonal corner portion and the third diagonal corner portion, the third end portion is disposed between the third diagonal corner portion and the second diagonal corner portion, and the fourth end portion is disposed between the second diagonal corner portion and the fourth diagonal corner portion; and

the first end portion, the second end portion, the third end portion, and the fourth end portion are correspondingly provided with the notches.

In the OLED display panel provided in the present invention, the second region comprises at least one sub-region disposed around the display region, and multiple notches are correspondingly defined in any of the at least one sub-region.

In the OLED display panel provided in the present invention, on any of the at least one sub-region, each of second spacers is between the adjacent notches, and the second spacers on the adjacent sub-regions are spaced apart.

In the OLED display panel provided in the present invention, the notch is a groove, or the notch is a through hole passing through the first inorganic layer.

In the OLED display panel provided in the present invention, a thickness of the first inorganic layer is 1 μm to 2 μm, and a thickness of the organic layer is 4 μm to 10 μm.

The present invention further provides a manufacturing method of an OLED display panel, comprising following steps:

providing a substrate, wherein the substrate comprises a display region, a first region disposed around the display region, and a second region disposed between the display region and the first region, and the second region is disposed around the display region;

forming a light-emitting functional layer on the display region and forming a retaining wall on the first region;

forming a first inorganic layer on the light-emitting functional layer, wherein the first inorganic layer extends to the retaining wall through the second region;

performing an image process on the first inorganic layer disposed in the second region to form a notch; and

forming an organic layer and a second inorganic layer sequentially on the first inorganic layer.

In the manufacturing method of the OLED display panel provided in the present invention, the first inorganic layer is provided with one notch, and the notch is disposed along a direction surrounding the display region.

In the manufacturing method of the OLED display panel provided in the present invention, the first inorganic layer is provided with multiple notches, and the notches are disposed at intervals along a direction surrounding the display region.

In the manufacturing method of the OLED display panel provided in the present invention, each of a plurality of first spacers is between adjacent notches, and a sum of lengths of the plurality of notches is greater or less than a sum of lengths of the plurality of first spacers.

In the manufacturing method of the OLED display panel provided in the present invention, the second region comprises at least one sub-region disposed around the display region, and multiple notches are correspondingly defined in any of the at least one sub-region.

In the manufacturing method of the OLED display panel provided in the present invention, on any of the at least one sub-region, each of second spacers is between the adjacent notches, and the second spacers on the adjacent sub-regions are spaced apart.

In the manufacturing method of the OLED display panel provided in the present invention, the notch is a groove, or the notch is a through hole passing through the first inorganic layer.

In the manufacturing method of the OLED display panel provided in the present invention, a thickness of the first inorganic layer is 1 μm to 2 μm, and a thickness of the organic layer is 4 μm to 10 μm.

### BENEFICIAL EFFECT

The present invention provides an OLED display panel and a manufacturing method thereof. By defining a notch on a first inorganic layer in a second region around a periphery of a display region, the notch can accommodate flowable organic materials, so that inkjet printed organic materials have a greatly reduced flow velocity at the periphery of the display region, which allows the organic materials to solidify and form an organic layer before they overflow the retaining wall, effectively preventing the organic materials from diffusing and overflowing, and thereby improving packaging effect of the thin film packaging layer.

### DESCRIPTION OF DRAWINGS

In order to more clearly illustrate the embodiments or the technical solutions in the prior art, a brief introduction of the drawings used in the embodiments or the prior art description will be briefly described below. Obviously, the drawings in the following description are only some of the embodiments of the invention, and those skilled in the art can obtain other drawings according to the drawings without any creative work.

FIG. 1 is a first schematic structural view of an OLED display panel according to the present invention.

FIG. 2 is a schematic structural view of a light-emitting functional layer in FIG. 1.

FIG. 3 is a first schematic plan view of the OLED display panel according to the present invention.

FIG. 4 is a second schematic plan view of the OLED display panel according to the present invention.

FIG. 5 is a third schematic plan view of the OLED display panel according to the present invention.

FIG. 6 is a fourth schematic plan view of the OLED display panel according to the present invention.

FIG. 7 is a second schematic structural view of the OLED display panel according to the present invention.

FIG. 8 is a third schematic structural view of the OLED display panel according to the present invention.

FIG. 9 is a fourth schematic structural view of the OLED display panel according to the present invention.

FIG. 10 is a fifth schematic structural view of the OLED display panel according to the present invention.

FIG. 11 is a fifth schematic plan view of the OLED display panel according to the present invention.

FIG. 12 is a flowchart of a manufacturing method of the OLED display panel according to the present invention.

### DETAILED DESCRIPTION OF PREFERRED EMBODIMENTS

The technical solution in the embodiments of the present invention will be clearly and completely described below with reference to the accompanying drawings in the embodiments of the present invention. It is to be understood that the described embodiments are merely exemplary of the invention, and not restrictive of the full scope of the invention. All other embodiments, which can be obtained by a person skilled in the art without inventive step based on the embodiments of the present invention, are within the scope of the present invention.

In the description of the present invention, it should be understood that the terms “first” and “second” are used for descriptive purposes only and are not to be construed as indicating or implying relative importance or implicitly indicating the number of technical features indicated. Thus, features defined as “first”, “second”, may explicitly or implicitly include one or more of the described features, and thus cannot be understood as a limitation on the present invention.

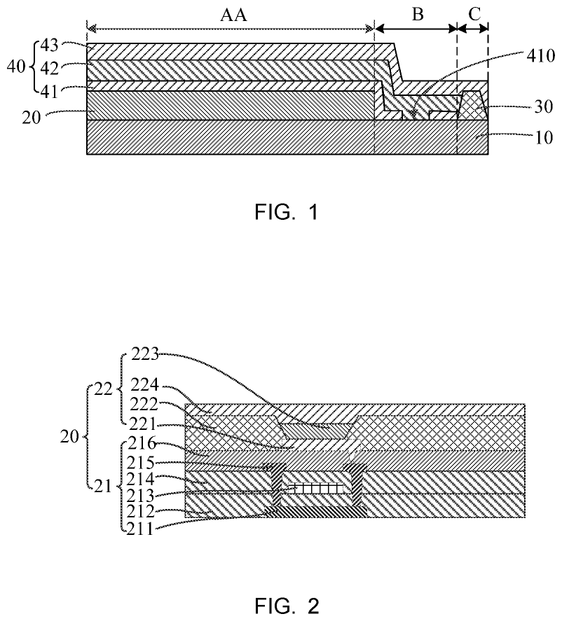

Please refer to FIG. 1 and FIG. 2, an embodiment of the present invention provides an OLED display panel. The OLED display panel comprises a substrate 10 comprising a display region AA, a first region C disposed around the display region AA, and a second region B disposed between the display region AA and the first region C, wherein the second region B is disposed around the display region AA; a light-emitting function layer 20 disposed on the display region AA; a retaining wall 30 disposed on the first region C; and a thin film packing layer 40 disposed on the light emitting functional layer 20 and extending to the retaining wall 30 through the second region B; wherein the thin film packing layer 40 comprises a first inorganic layer 41, an organic layer 42, and a second inorganic layer 43 disposed in a stack, and a notch 410 is defined in the first inorganic layer 41 disposed in the second region B.

The substrate 10 may be a polyimide (PI) flexible substrate (polyimide film). The substrate 10 may be composed of one or more PI flexible substrates, which is not limited in the present invention.

The light-emitting functional layer 20 comprises an array layer 21 and a light-emitting layer 22 which are arranged in a stack. Specifically, the array layer 21 comprises, but is not limited to, an active layer 211, a first dielectric insulating layer 212, a gate metal layer 213, a second dielectric insulating layer 214, a source-drain metal layer 215, and a planarization layer 216, which are arranged in a stack. The light emitting layer 22 comprises, but is not limited to, a pixel electrode layer 221, a pixel definition layer 222, a light-emitting material layer 223, and a cathode layer 224, which are arranged in a stack. The specific structure of each film layer is the conventional prior art, which is not described in the present invention.

The retaining wall 30 is disposed around a periphery of the display region AA. The retaining wall 30 may be disposed on a same layer as a functional film layer in the light-emitting functional layer 20, such as the pixel definition layer 222. The retaining wall 30 can also be disposed on the same layer as several functional film layers in the light-emitting functional layer 20, such as the planarization layer 216 and the pixel definition layer 222 that are arranged in a stack. The retaining wall 30 may also be formed by stacking other inorganic materials and/or organic materials separately; the present invention does not specifically limit thereto.

The thin film packing layer 40 may comprise a film layer structure having multilayer with inorganic/organic/inorganic overlapping film layers. In the embodiment of the present invention, the thin film packing layer 40 comprises a first inorganic layer 41, an organic layer 42, and a second inorganic layer 43 which are arranged in a stack as an example for description. The first inorganic layer 41 and the second inorganic layer 43 may have a single-layer or multi-layer structure of silicon dioxide, silicon nitride, silicon oxynitride, or amorphous silicon, so as to prevent intrusion of external water vapor and oxygen. The organic layer 42 may be one or more of acrylic resin, polycarbonate, and polystyrene. The organic layer 42 may be used to slow down stresses in the first inorganic layer 41 and the second inorganic layer 43, thereby enhancing flexibility of the OLED display panel. The organic layer 42 is usually formed by an inkjet printing process. However, when the organic layer 42 is formed by inkjet printing, a material of the organic layer 42 has a certain fluidity before forming the fixedly formed organic layer 42 and flows from the display region AA to the retaining wall 30.

The notch 410 is defined in the second region B between the display region AA and the retaining wall 30 and can accommodate a certain amount of the organic materials to prevent the organic materials from overflowing the retaining wall. In addition, a shape and number of the notch 410 can be set according to the actual situation. For example, the notch 410 may be a bar shape, an arc shape, or triangular; the notch 410 may be provided as one or may be provided as multiple. The present invention does not limit thereto.

In the embodiment of the present invention, the notch 410 is disposed on the first inorganic layer 41 in the second region B around the display region AA, and the notch 410 can accommodate the flowable organic materials, so that the flow velocity of the inkjet printed organic materials in the peripheral region of the display region AA is greatly reduced, and the organic materials are solidified to form the organic layer 42 before overflowing the retaining wall 30. This effectively prevents diffusion and overflow of the organic materials, thereby improving packaging effect of the thin film packaging layer 40.

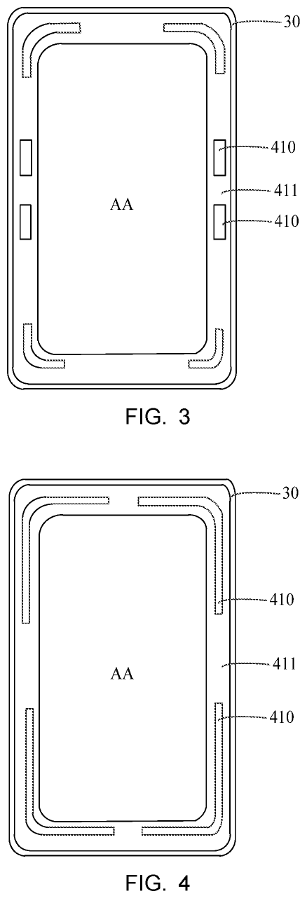

Specifically, please refer to FIG. 3, in the embodiment of the present invention, a plurality of notches 410 are defined in the second region B, and the plurality of notches 410 are spaced apart along a direction surrounding the display region AA. Each of a plurality of first spacers 411 is between the adjacent notches 410. The first spacer 411 is the remaining first inorganic layer 41. When the notch 410 accommodates the flowable organic materials, the first spacer 411 can extend a path for water and oxygen to intrude the light-emitting functional layer 20 through the organic materials, thereby effectively improving package reliability.

In some embodiments, please continue to refer to FIG. 3. In a direction surrounding the display region AA, a sum of lengths of the plurality of notches 410 is less than a sum of lengths of the plurality of first spacers 411. While the notch 410 has buffering effect on the flow of the organic materials, the first spacer 411 can be used to effectively extend the path for water and oxygen to intrude the light-emitting functional layer 20 through the organic materials, thereby improving the package reliability. It should be noted that, on this basis, a number or specific distribution of each notch 410 and each first spacer 411 is not specifically limited in the embodiment of the present invention.

In some embodiments, please refer to FIG. 4. In the direction surrounding the display region AA, the sum of the lengths of the plurality of notches 410 is greater than the sum of the lengths of the plurality of first spacers 411. The notch 410 can have more space to accommodate the organic materials, which can more effectively buffer the flow of the organic materials, thereby preventing the overflow of the organic materials. Meanwhile, the remaining first spacer 411 can also play a certain effect of blocking water and oxygen. It should be noted that, on this basis, the number or specific distribution of each notch 410 and each first spacer 411 is not specifically limited in the embodiment of the present invention.

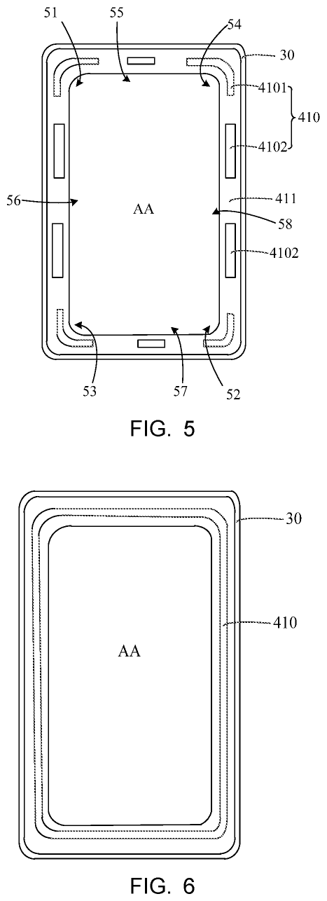

In the embodiment of the present invention, please refer to FIG. 5, the display region AA comprises a first diagonal corner portion 51 and a second diagonal corner portion 52 disposed opposite to each other, and a third diagonal corner portion 53 and a fourth diagonal corner portion 54 disposed opposite to each other. The first diagonal corner portion 51, the second diagonal corner portion 52, the third diagonal corner portion 53, and the fourth diagonal corner portion 54 are correspondingly provided with the notches 410.

Accordingly, the display region AA further comprises a first end portion 55, a second end portion 56, a third end portion 57, and a fourth end portion 58. The first end portion 55 is disposed between the first diagonal corner portion 51 and the fourth diagonal corner portion 54. The second end portion 56 is disposed between the first diagonal corner portion 51 and the third diagonal corner portion 53. The third end portion 57 is disposed between the third diagonal corner portion 53 and the second diagonal corner portion 52 The fourth end portion 58 is disposed between the second diagonal corner portion 52 and the fourth diagonal corner portion 54. The first end portion 55, the second end portion 56, the third end portion 57, and the fourth end portion 58 are correspondingly provided with the notches 410.

Further, the notch 410 comprises a first notch 4101 and a second notch 4102. The first notch 4101 is arc-shaped, and the second notch 4102 is strip-shaped. The first diagonal corner portion 51, the second diagonal corner portion 53, the third diagonal corner portion 53, and the fourth diagonal corner portion 54 are correspondingly provided with the first notches 4101. The first end portion 55, the second end portion 56, the third end portion 57, and the fourth end portion 58 are correspondingly provided with the second notches 4102. It can be understood that, for a conventional display panel, in order to obtain an aesthetic effect, the four corners of the rectangular display region AA are usually set as arc-shaped corners. Therefore, in the second region B, first arc-shaped notches 4101 corresponding to the first diagonal corner portion 51, the second diagonal corner portion 52, the third diagonal corner portion 53, and the fourth diagonal corner portion 54 are provided. The notches 4101 correspond to the four corner shapes of the display region AA, which can effectively maintain uniformity of the flow of the organic materials at the corners of the display region AA, thereby ensuring thickness consistency of the organic layer 42.

Further, the second notches 4102 disposed corresponding to the first end portion 55 and the third end portion 57 are symmetrically distributed; the second notches 4102 disposed corresponding to the second end portion 56 and the fourth end portion 58 are symmetrically distributed. The distribution of the second notches 410 corresponding to the first diagonal corner portion 51, the second diagonal corner portion 52, the third diagonal corner portion 53, and the fourth diagonal corner portion 54 is the same. The symmetrical arrangement of the notches 410 allows the organic materials to flow at the same speed toward the periphery of the display region AA during the flow process, and the thickness of the organic layer 42 formed at the end is uniform, thereby improving the flexibility of the OLED display panel and effectively relieving stress in the first inorganic layer 41.

Please refer to FIG. 6, in the embodiment of the present invention, only one notch 410 is defined in the second region B, and the notch 410 is disposed along a direction surrounding the display region AA. Setting the notch 410 around the entire display region AA can effectively increase the space for containing the organic materials, thereby improving the package reliability and effectively delaying the overflow of the organic materials.

In addition, in the embodiment of the present invention, a thickness of the first inorganic layer 41 is 1 μm to 2 μm. A thickness of the organic layer 42 is 4 μm to 10 μm. The notch 410 may be a groove, or the notch 410 may be a through hole passing through the first inorganic layer 41.

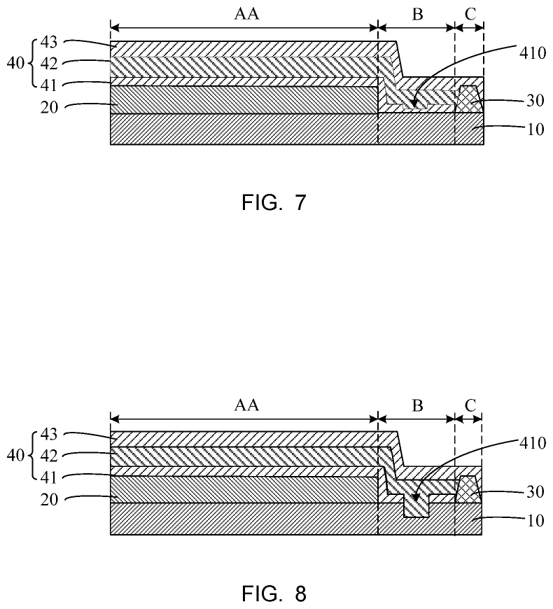

Specifically, please refer to FIG. 7, when a depth of the notch 410 is less than the thickness of the first inorganic layer 41 in a direction perpendicular to the substrate 10, the notch 410 is shown as a groove on the first inorganic layer 41. Meanwhile, the notch 410 does not pass through the first inorganic layer 41. After the notch 410 is filled with the organic materials, the first inorganic layer 41 remaining under the notch 410 can effectively prevent outside water and oxygen from eroding the light-emitting functional layer 42 through the organic materials in the notch 410, thereby improving the package reliability.

Further, when the notch 410 is a groove that does not pass through the first inorganic layer 41, only one notch 410 may be defined in the second region B, and the notch 410 is disposed along a direction surrounding the display region AA. Meanwhile, because the first inorganic layer 41 remaining under the notch 410 can effectively block water and oxygen, disposing the entire notch 410 surrounding the display region AA can increase the space for accommodating the organic materials, thereby improving the package reliability and further preventing the diffusion and overflow of the organic materials.

Please refer to FIG. 1 and FIG. 8, when the notch 410 is equal to or greater than the thickness of the first inorganic layer 41 in a direction perpendicular to the substrate 10, the notch 410 is shown as a through hole in the first inorganic layer 41. Specifically, the notch 410 may only pass through the first inorganic layer 41; the notch 410 may also pass through the first inorganic layer 41 and extend to the substrate 10. When the notch 410 extends to the substrate 10, the space where the notch 410 accommodates the organic materials can be increased, and the organic materials can be more effectively prevented from overflowing the retaining wall 30 through the second region B.

In addition, in the embodiment of the present invention, the first inorganic layer 41 and/or the second inorganic layer 43 may extend to the retaining wall 30 and completely cover the retaining wall 30. It can prevent outside water and oxygen from invading into the OLED display panel through the side of the retaining wall 30 away from the display region AA, thereby further improving the package reliability of the thin film packaging layer 40.

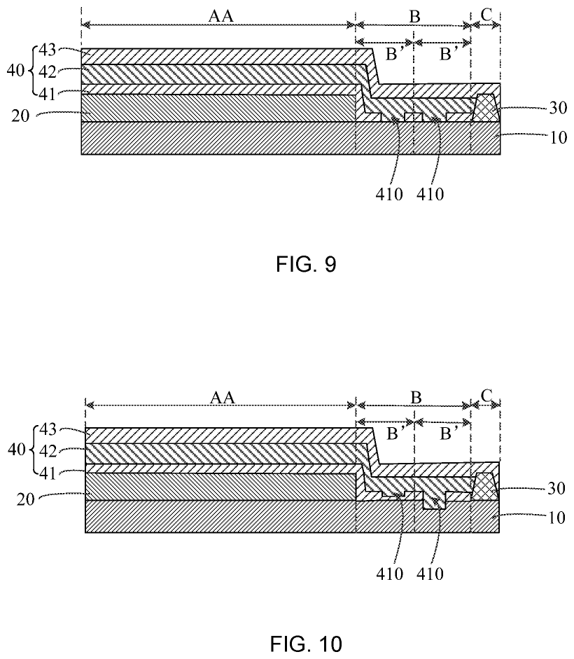

Please refer to FIG. 9, in some embodiments, the second region B comprises at least one sub-region B′, and the sub-region B′ is disposed around the display region AA. Multiple notches 410 are correspondingly defined in any of the at least one sub-region B′. By disposing a plurality of sub-regions B′ with notches 410 around the periphery of the display region AA, after the notches 410 near the display region AA are filled by the flowing organic materials, the notches 410 in the adjacent sub-regions B′ can further accommodate the organic materials and reduce risk of the organic materials overflowing the retaining wall 30.

It should be noted that the notches 410 in the plurality of sub-regions B′ may be set as the above-mentioned grooves or through holes; the plurality of sub-regions B′ may be provided with one notch 410 surrounding the display region AA or multiple notches 410 arranged at intervals. Specifically, please refer to FIG. 10, in the embodiment of the present invention, two sub-regions B′ are disposed on the periphery of the display region AA, and the notch 410 near a boundary of the display region AA is set as a groove. The notch 410 far from the boundary of the display region AA is set as a through hole extending to the substrate 10 as an example for illustration. After the notch 410 near the boundary of the display region AA is filled with the organic materials, the first inorganic layer 41 remaining under the notch 410 can effectively prevent outside water and oxygen from eroding the light-emitting functional layer 42 through the organic materials in the notch 410. Meanwhile, the notch 410 away from the boundary of the display region AA accommodates more organic materials, which can further prevent the organic materials from flowing out of the retaining wall 30. The embodiment of the present invention can effectively improve the package reliability while effectively preventing the overflow of the organic materials.

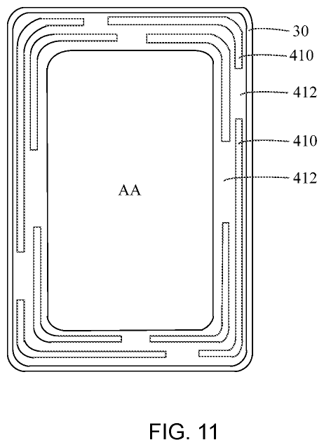

Further, please refer to FIG. 11, on any of the at least one sub-region B′, each of second spacers 412 is between the adjacent notches 410, and the second spacers 412 on the adjacent sub-regions B′ are spaced apart. Because the second spacers 412 on the adjacent sub-region B′ are spaced apart, a path for the external water and oxygen to pass through the organic light-emitting layer 20 through the organic materials in the notch 410 is effectively extended, and the package reliability is further improved.

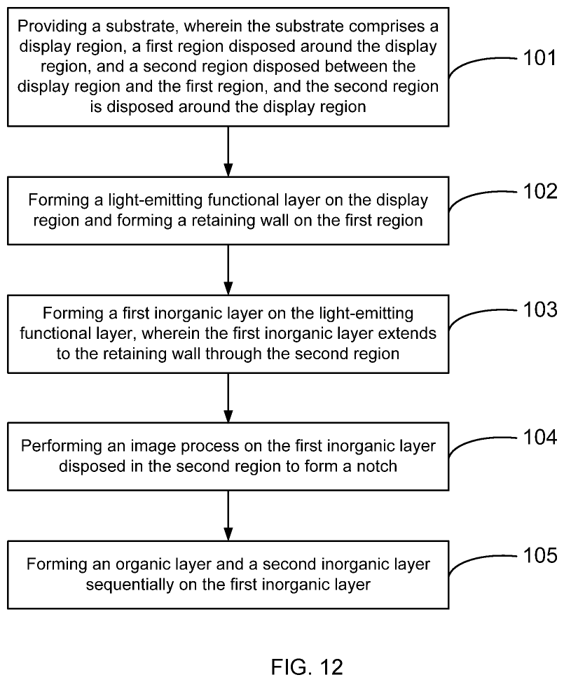

The present invention further provides a manufacturing method of the OLED display panel. Please refer to FIG. 1, FIG. 2, and FIG. 12. The specific manufacturing steps are as follows:

101, providing a substrate, wherein the substrate comprises a display region, a first region disposed around the display region, and a second region disposed between the display region and the first region, and the second region is disposed around the display region.

The substrate 10 may be a polyimide (PI) flexible substrate (polyimide film). The substrate 10 may comprise one or more PI films, which is not limited in the present invention.

102, forming a light-emitting functional layer on the display region and forming a retaining wall on the first region.

The light-emitting functional layer 20 comprises an array layer 21 and a light-emitting layer 22 which are arranged in a stack. Specifically, the array layer 21 comprises, but is not limited to, an active layer 211, a first dielectric insulating layer 212, a gate metal layer 213, a second dielectric insulating layer 214, a source-drain metal layer 215, and a planarization layer 216, which are arranged in a stack. The light emitting layer 22 comprises, but is not limited to, a pixel electrode layer 221, a pixel definition layer 222, a light-emitting material layer 223, and a cathode layer 224, which are arranged in a stack. The array layer 21 and the light-emitting layer 22 are formed on the display region AA in turn. The specific process is the conventional prior art, which is not described thereto.

The retaining wall 30 can be formed by using the same process when forming a certain functional film layer in the light-emitting functional layer 20. For example, when the pixel definition layer 222 is formed in the display region AA, the retaining wall 30 is formed on the same layer in the first region C. Or, when the planarization layer 216 is formed in the display region AA, a part of the retaining wall 30 is formed on the same layer in the first region C, and then when the pixel definition layer 222 is formed on the planarization layer 216, another part of the retaining wall 30 is formed on the same layer in the first region C. That is, the retaining wall 30 is composed of the planarization layer 216 and the pixel definition layer 222 arranged in a stack. This solution can save process and reduce production costs.

103, forming a first inorganic layer on the light-emitting functional layer, wherein the first inorganic layer extends to the retaining wall through the second region.

Specifically, the first inorganic layer 41 may be formed by an evaporation process, a chemical vapor deposition process, or other processes.

104, performing an image process on the first inorganic layer disposed in the second region to form a notch.

Specifically, the first inorganic layer 41 disposed in the second region B may be dry-etched to obtain the notch 410. The specific etching pattern of the notch 410 can be set according to the actual situation, which is not limited thereto.

105, forming an organic layer and a second inorganic layer sequentially on the first inorganic layer.

Specifically, the second inorganic layer 43 may be formed by an evaporation process, a chemical vapor deposition process, or other processes. The organic layer 42 is formed by an inkjet printing process. When the organic layer 42 is formed using the inkjet printing process, the organic materials are inkjet printed on the first inorganic layer 41 disposed in the display region AA. The second inorganic layer 42 may extend to the retaining wall 30 through the second region B.

It should be noted that the present invention only uses the thin film packing layer 40 to comprise the first inorganic layer 41, the second inorganic layer 42, and the third inorganic layer 43 as an example for description, but it cannot be construed as limiting the present invention.

In addition, when the first inorganic layer 41 and the second inorganic layer 43 are deposited, the first inorganic layer 41 and/or the second inorganic layer 43 may be extended to the retaining wall 30 and completely cover the retaining wall 30 to further preventing outside water and oxygen from invading into the OLED display panel through the side of the retaining wall 30 away from the display region AA, thereby further improving reliability of the thin film packing layer 40.

In the embodiment of the present invention, the first inorganic layer 41 in the second region B around the display region AA is etched to form the notch 410. The notch 410 is used to contain the flowable organic materials, so that inkjet printed organic materials have a greatly reduced flow velocity at the periphery of the display region AA, and the organic materials are solidified to form the organic layer 42 before overflowing the retaining wall 30, which effectively prevents the organic materials from diffusing and overflowing the retaining wall 30, thereby improving the packaging effect.

The embodiments of the present invention have been described in detail above. Specific examples are used to explain principles and implementation of the present invention. The description of the above embodiments is only used to help understand the method of the application and its core ideas. Meanwhile, for those of ordinary skill in the art, according to the idea of the present invention, there will be changes in the specific implementation and application scope. In the above, contents of the description should not be construed as a limitation on the present invention.

What is claimed is:

1. An OLED display panel, comprising:
a substrate comprising a display region, a first region disposed around the display region, and a second region disposed between the display region and the first region, wherein the second region is disposed around the display region;
a light-emitting function layer disposed on the display region;
a retaining wall disposed on the first region; and
a thin film packing layer disposed on the light emitting functional layer and extending to the retaining wall through the second region; and
wherein the thin film packing layer comprises a first inorganic layer, an organic layer, and a second inorganic layer disposed in a stack, and a notch is defined in the first inorganic layer disposed in the second region.

2. The OLED display panel as claimed in claim 1, wherein the first inorganic layer is provided with one notch, and the notch is disposed along a direction surrounding the display region.

3. The OLED display panel as claimed in claim 1, wherein the first inorganic layer is provided with multiple notches, and the notches are disposed at intervals along a direction surrounding the display region.

4. The OLED display panel as claimed in claim 3, wherein each of a plurality of first spacers is between adjacent notches, and a sum of lengths of the plurality of notches is greater or less than a sum of lengths of the plurality of first spacers.

5. The OLED display panel as claimed in claim 4, wherein the display region comprises a first diagonal corner portion and a second diagonal corner portion disposed opposite to each other, and a third diagonal corner portion and a fourth diagonal corner portion disposed opposite to each other; and
the first diagonal corner portion, the second diagonal corner portion, the third diagonal corner portion, and the fourth diagonal corner portion are correspondingly provided with the notches.

6. The OLED display panel as claimed in claim 5, wherein the display region further comprises a first end portion, a second end portion, a third end portion, and a fourth end portion, the first end portion is disposed between the first diagonal corner portion and the fourth diagonal corner portion, the second end portion is disposed between the first diagonal corner portion and the third diagonal corner portion, the third end portion is disposed between the third diagonal corner portion and the second diagonal corner portion, and the fourth end portion is disposed between the second diagonal corner portion and the fourth diagonal corner portion; and
the first end portion, the second end portion, the third end portion, and the fourth end portion are correspondingly provided with the notches.

7. The OLED display panel as claimed in claim 6, wherein the notches comprise first notches and second notches, the first notches are arc-shaped, and the second notches are strip-shaped; and
the first diagonal corner portion, the second diagonal corner portion, the third diagonal corner portion, and the fourth diagonal corner portion are correspondingly provided with the first notches, and the first end portion, the second end portion, the third end portion, and the fourth end portion are correspondingly provided with the second notches.

8. The OLED display panel as claimed in claim 1, wherein the second region comprises at least one sub-region disposed around the display region, and multiple notches are correspondingly defined in any of the at least one sub-region.

9. The OLED display panel as claimed in claim 8, wherein on any of the at least one sub-region, each of second spacers is between adjacent notches, and the second spacers on adjacent sub-regions are spaced apart.

10. The OLED display panel as claimed in claim 1, wherein the notch is a groove, or the notch is a through hole passing through the first inorganic layer.

11. The OLED display panel as claimed in claim 1, wherein a thickness of the first inorganic layer is 1 μm to 2 μm, and a thickness of the organic layer is 4 μm to 10 μm.

12. A manufacturing method of an OLED display panel, comprising following steps:
providing a substrate, wherein the substrate comprises a display region, a first region disposed around the display region, and a second region disposed between the display region and the first region, and the second region is disposed around the display region;
forming a light-emitting functional layer on the display region and forming a retaining wall on the first region;
forming a first inorganic layer on the light-emitting functional layer, wherein the first inorganic layer extends to the retaining wall through the second region;
performing an image process on the first inorganic layer disposed in the second region to form a notch; and
forming an organic layer and a second inorganic layer sequentially on the first inorganic layer.

13. The manufacturing method of the OLED display panel as claimed in claim 12, wherein the first inorganic layer is provided with one notch, and the notch is disposed along a direction surrounding the display region.

14. The manufacturing method of the OLED display panel as claimed in claim 12, wherein the first inorganic layer is provided with multiple notches, and the notches are disposed at intervals along a direction surrounding the display region.

15. The manufacturing method of the OLED display panel as claimed in claim 12, wherein each of a plurality of first spacers is between adjacent notches, and a sum of lengths of the plurality of notches is greater or less than a sum of lengths of the plurality of first spacers.

16. The manufacturing method of the OLED display panel as claimed in claim 12, wherein the second region comprises at least one sub-region disposed around the display region, and multiple notches are correspondingly defined in any of the at least one sub-region.

17. The manufacturing method of the OLED display panel as claimed in claim 16, wherein on any of the at least one sub-region, each of second spacers is between adjacent notches, and the second spacers on adjacent sub-regions are spaced apart.

18. The manufacturing method of the OLED display panel as claimed in claim 12, wherein the notch is a groove, or the notch is a through hole passing through the first inorganic layer.

19. The manufacturing method of the OLED display panel as claimed in claim 12, wherein a thickness of the first inorganic layer is 1 μm to 2 μm, and a thickness of the organic layer is 4 μm to 10 μm.
